(19) United States
(12) Patent Application Publication
(10) Pub. No.: US 2013/0070366 A1
(43) Pub. Date: Mar. 21, 2013

(54) MAGNETIC RECORDING HEAD WITH LOW-WEAR PROTECTIVE FILM HAVING HYDROGEN AND/OR WATER VAPOR THEREIN

(71) Applicants: Mineaki Kodama, Odawara-shi (JP); Kazuhito Miyata, Fujisawa-shi (JP); Hiroshi Ishizaki, Naka-gun (JP); Atsuko Okawa, Yokohama (JP)

(72) Inventors: Mineaki Kodama, Odawara-shi (JP); Kazuhito Miyata, Fujisawa-shi (JP); Hiroshi Ishizaki, Naka-gun (JP); Atsuko Okawa, Yokohama (JP)

(73) Assignee: Hitachi Global Storage Technologies Netherlands B.V., Amsterdam (NL)

(21) Appl. No.: 13/239,244

(22) Filed: Sep. 21, 2011

(51) Int. Cl. G11B 5/33; B05D 5/12; C23C 14/34; G11B 21/02

(52) U.S. Cl. 360/75; 427/58; 204/192.38; 428/810; G9B/21.003

(57) ABSTRACT

According to one embodiment, a method for manufacturing a magnetic device includes forming a protective film above a structure, wherein at least one of hydrogen and water vapor are introduced into a formation chamber during formation of the protective film. In-another embodiment, a magnetic head includes at least one of: a read element, a write element, a heater element, and a resistance detector element above a substrate, conductive terminals for each of the at least one of: the read element, the write element, and the heater element, and a protective film above the at least one of: the read element, the write element, and the heater element, wherein the protective film comprises at least one of hydrogen and water vapor.

### FIELD OF THE INVENTION

The present application relates to magnetic heads and methods of producing the same. In particular, the present application relates to a protective film for a magnetic head that comprises hydrogen and/or water vapor, magnetic heads implementing the same, and methods for producing the same.

### BACKGROUND

Recent progress in achieving high recording densities at low cost has resulted in magnetic disk drives, such as hard disk drives (HDDs), that are in widespread use, such as for large external recording devices for computers and as digital data storage media for the information technology (IT) industry.

Currently, in order to cope with increasing recording densities demanded by users of magnetic disk drives, it has been essential to reduce the magnetic spacing, or the spacing between elements formed on a magnetic head and the corresponding magnetic film on the magnetic disk. By reducing this magnetic spacing, the effective magnetic field effects on both sides of the magnetic film may be increased, thereby raising the recording density of the magnetic disks.

According to current understanding in the art, magnetic spacing is primarily determined by three main factors: the medium, space, and head factors. The medium factor relates to the thickness of the protective film and lubricating film of the magnetic disk, the space factor relates to the clearance between the magnetic disk and the magnetic head, and the head factor relates to the film thickness of the air bearing surface overcoat (ABSOC) film formed on the air bearing surface of the magnetic head. The ABSOC film is the surface of the magnetic head facing the magnetic disk, which has a purpose of providing corrosion resistance and wear resistance to the magnetic head.

In some conventional approaches, in order to improve recording density, the film thicknesses of the protective film and the lubricating film for the magnetic disk and the ABSOC film have been reduced. The ABSOC film thickness in particular has been reduced using technologies such as cathodic arc film formation, as disclosed for example in Japanese Patent No. 2003-239062.

In other approaches, the ABSOC film formed on the ABS of the magnetic head may have a dual-layer structure consisting of an adhesive film and a protective film. There are several factors to consider in choosing materials for the ABSOC film, including being able to prevent peeling of the protective layer, function as an adhesive layer for the protective film on the magnetic head, prevent corrosion of the magnetic elements due to atmospheric effects, and provide resistance against wear on the magnetic head surface through contact between the magnetic head and the magnetic disk. To fulfill these functions, the protective film must exhibit a high density and hardness. As described above, with conventional technology it is possible to create a dense and hard protective film using a cathodic arc film-forming technique, which has contributed to the reduction of ABSOC film thickness and magnetic spacing. However, in such conventional approaches, the protection against corrosion and wear rapidly deteriorate at protective film thicknesses of about 10 Å or less, and it is difficult to find ways of further reducing the thickness of the protective film.

Therefore, it would be of great utility to provide a system and method for producing magnetic heads with a protective film that resolves the above difficulties, and provides a magnetic head with superior wear resistance and higher density than in the prior art for a magnetic head which employs a diamond-like carbon (DLC) film formed using a cathodic arc film-forming process.

### SUMMARY

According to one embodiment, a method for manufacturing a magnetic device includes forming a protective film above a structure, wherein at least one of hydrogen and water vapor are introduced into a formation chamber during formation of the protective film.

In another embodiment, a magnetic head includes at least one of: a read element, a write element, a heater element, and a resistance detector element above a substrate, conductive terminals for each of the at least one of: the read element, the write element, and the heater element, and a protective film above the at least one of: the read element, the write element, and the heater element, wherein the protective film comprises at least one of hydrogen and water vapor.

Any of these embodiments may be implemented in a magnetic data storage system such as a disk drive system, which may include a magnetic head, a drive mechanism for passing a magnetic storage medium (e.g., hard disk) over the head, and a control unit electrically coupled to the head for controlling operation of the head.

Other aspects and advantages of the present invention will become apparent from the following detailed description, which, when taken in conjunction with the drawings, illustrate by way of example the principles of the invention.

### BRIEF DESCRIPTION OF THE DRAWINGS

FIG. 1 is a simplified drawing of a magnetic recording disk drive system.

FIG. 2A is a schematic representation in section of a recording medium utilizing a longitudinal recording format.

FIG. 2B is a schematic representation of a conventional magnetic recording head and recording medium combination for longitudinal recording as in FIG. 2A.

FIG. 2C is a magnetic recording medium utilizing a perpendicular recording format.

FIG. 2D is a schematic representation of a recording head and recording medium combination for perpendicular recording on one side.

FIG. 2E is a schematic representation of a recording apparatus adapted for recording separately on both sides of the medium.

FIG. 3A is a cross-sectional view of one particular embodiment of a perpendicular magnetic head with helical coils.

FIG. 3B is a cross-sectional, view of one particular embodiment of a piggyback magnetic head with helical coils.

FIG. 4A is a cross-sectional view of one particular embodiment of a perpendicular magnetic head with looped coils.

FIG. 4B is a cross-sectional view of one particular embodiment of a piggyback magnetic head with looped coils.

FIG. 5 is a cross-sectional schematic view of an air bearing surface overcoat (ABSOC) film, according to one embodiment.

FIG. 6A is a schematic view of a magnetic head, according to the prior art.

FIG. 6B is a cross-sectional schematic view of a magnetic head, according to the prior art.

FIG. 7 shows a schematic view of a device for forming a protective film on a magnetic head, according to one embodiment.

FIG. 8 is a chart showing the D-band peak strength in the vicinity of 1350 cm⁻¹ and G-band peak strength in the vicinity of 1530 cm⁻¹, according to one embodiment.

FIG. 9 shows the results of measuring the proportion of sp3 bonding using x-ray electronic spectroscopy, according to one embodiment.

FIG. 10 shows the quantities of elements found from the results of RBS and ERDA analysis using an energy ion beam analysis device, according to one embodiment.

FIG. 11 is a chart showing a relationship between sp3 bonding and the hydrogen content of DLC film, according to one embodiment.

FIG, 12 shows results of a head scratch test, according to one embodiment.

FIG. 13 shows results of an Auger analysis on the scratch marks, according to one embodiment.

FIG. 14 shows the results of monitoring the levels of wear in the magnetic head protective film with a magnetic head formed with the carbon protective film of embodiment and the comparative example, according to one embodiment.

### DETAILED DESCRIPTION

The following description is made for the purpose of illustrating the general principles of the present invention and is not meant to limit the inventive concepts claimed herein. Further, particular features described herein can be used in combination with other described features in each of the various possible combinations and permutations.

Unless otherwise specifically defined herein, all terms are to be given their broadest possible interpretation including meanings implied from the specification as well as meanings understood by those skilled in the art and/or as defined in dictionaries, treatises, etc.

It must also be noted that, as used in the specification and the appended claims, the singular forms “a,” “an” and “the” include plural referents unless otherwise specified.

According to one general embodiment, a method for manufacturing a magnetic device includes forming a protective film above a structure, wherein at least one of hydrogen and water vapor are introduced into a formation chamber during formation of the protective film.

In another general embodiment, a magnetic head includes at least one of: a read element, a write element, a heater element, and a resistance detector element above a substrate, conductive terminals for each of the at least one of: the read element, the write element, and the heater element, and a protective film above the at least one of: the read element, the write element, and the heater element, wherein the protective film comprises at least one of hydrogen and water vapor.

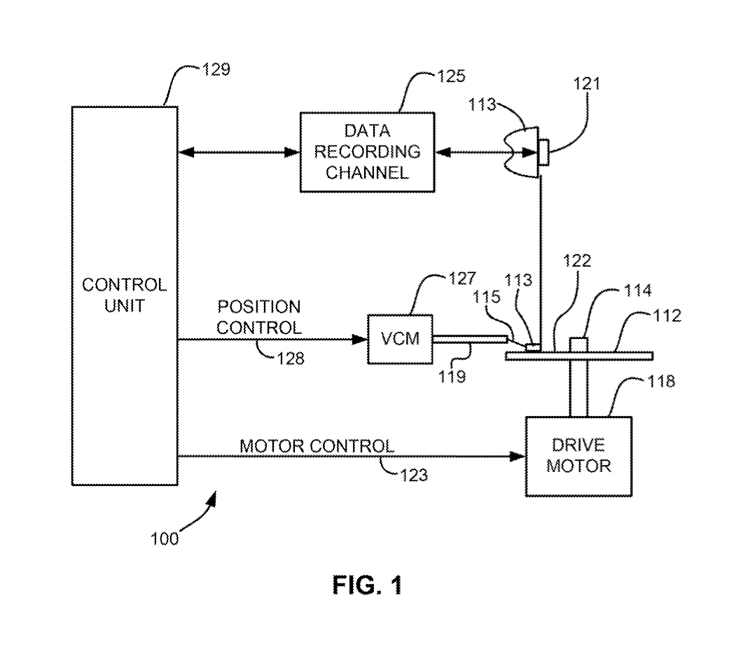

Referring now to FIG. 1, there is shown a disk drive 100 in accordance with one embodiment of the present invention. As shown in FIG. 1, at least one rotatable magnetic disk 112 is supported on a spindle 114 and rotated by a disk drive motor 118. The magnetic recording on each disk is typically in the form of an annular pattern of concentric data tracks (not shown) on the disk 112.

At least one slider 113 is positioned near the disk 112, each slider 113 supporting one or more magnetic read/write heads 121. As the disk rotates, slider 113 is moved radially in and out over disk surface 122 so that heads 121 may access different tracks of the disk where desired data are recorded and/or to be written. Each slider 113 is attached to an actuator arm 119 by means of a suspension 115. The suspension 115 provides a slight spring force which biases slider 113 against the disk surface 122. Each actuator arm 119 is attached to an actuator 127. The actuator 127 as shown in FIG. 1 may be a voice coil motor (VCM). The VCM comprises a coil movable within a fixed magnetic field, the direction and speed of the coil movements being controlled by the motor current signals supplied by controller 129.

During operation of the disk storage system, the rotation of disk 112 generates an air bearing between slider 113 and disk surface 122 which exerts an upward force or lift on the slider. The air bearing thus counter-balances the slight spring force of suspension 115 and supports slider 113 off and slightly above the disk surface by a small, substantially constant spacing during normal operation. Note that in some embodiments, the slider 113 may slide along the disk surface 122.

The various components of the disk storage system are controlled in operation by control signals generated by control unit 129, such as access control signals and internal clock signals. Typically, control unit 129 comprises logic control circuits, storage (e.g., memory), and a microprocessor. The control unit 129 generates control signals to control various system operations such as drive motor control signals on line 123 and head position and seek control signals on line 128. The control signals on line 128 provide the desired current profiles to optimally move and position slider 113 to the desired data track on disk 112. Read and write signals are communicated to and from read/write heads 121 by way of recording channel 125.

The above description of a typical magnetic disk storage system, and the accompanying illustration of FIG. 1 is for representation purposes only. It should be apparent that disk storage systems may contain a large number of disks and actuators, and each actuator may support a number of sliders.

An interface may also be provided for communication between the disk drive and a host (integral or external) to send and receive the data and for controlling the operation of the disk drive and communicating the status of the disk drive to the host, all as will be understood by those of skill in the art.

In a typical head, an inductive write head includes a coil layer embedded in one or more insulation layers (insulation stack), the insulation stack being located between first and second pole piece layers. A gap is formed between the first and second pole piece layers by a gap layer at an air bearing surface (ABS) of the write head. The pole piece layers may be connected at a back gap. Currents are conducted through the coil layer, which produce magnetic fields in the pole pieces. The magnetic fields fringe across the gap at the ABS for the purpose of writing bits of magnetic field information in tracks on moving media, such as in circular tracks on a rotating magnetic disk.

The second pole piece layer has a pole tip portion which extends from the ABS to a flare point and a yoke portion which extends from the flare point to the back gap. The flare point is where the second pole piece begins to widen (flare) to form the yoke. The placement of the flare point directly affects the magnitude of the magnetic field produced to write information on the recording medium.

According to one illustrative embodiment, a magnetic data storage system may comprise at least one magnetic head as described herein according to any embodiment, a magnetic medium, a drive mechanism for passing the magnetic medium over the at least one magnetic head, and a controller electrically coupled to the at least one magnetic head for controlling operation of the at least one magnetic head.

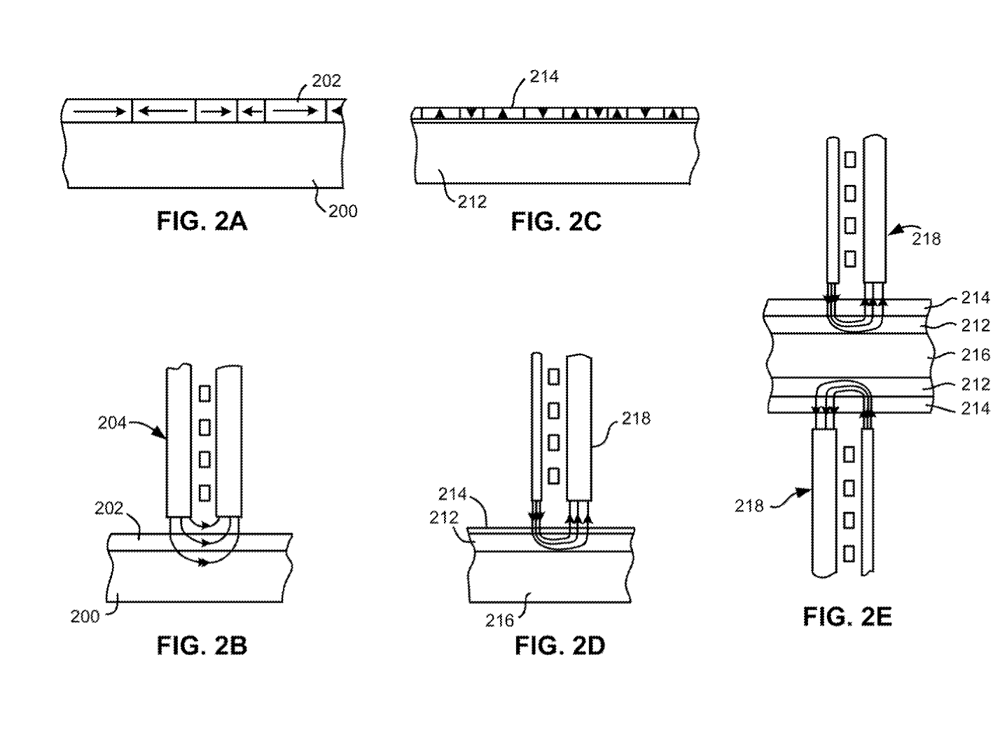

FIG. 2A illustrates, schematically, a conventional recording medium such as used with magnetic disc recording systems, such as that shown in FIG. 1. This medium is utilized for recording magnetic impulses in or parallel to the plane of the medium itself. The recording medium, a recording disc in this instance, comprises basically a supporting substrate 200 of a suitable non-magnetic material such as glass, with an overlying coating 202 of a suitable and conventional magnetic layer.

FIG. 2B shows the operative relationship between a conventional recording/playback head 204, which may preferably be a thin film head, and a conventional recording medium, such as that of FIG. 2A.

FIG. 2C illustrates, schematically, the orientation of magnetic impulses substantially perpendicular to the surface of a recording medium as used with magnetic disc recording systems, such as that shown in FIG. 1. For such perpendicular recording the medium typically includes an under layer 212 of a material having a high magnetic permeability. This under layer 212 is then provided with an overlying coating 214 of magnetic material preferably having a high coercivity relative to the under layer 212.

FIG. 2D illustrates the operative relationship between a perpendicular head 218 and a recording medium. The recording medium illustrated in FIG. 2D includes both the high permeability under layer 212 and the overlying coating 214 of magnetic material described with respect to FIG. 2C above. However, both of these layers 212 and 214 are shown applied to a suitable substrate 216. Typically there is also an additional layer (not shown) called an “exchange-break” layer or “interlayer” between layers 212 and 214.

In this structure, the magnetic lines of flux extending between the poles of the perpendicular head 218 loop into and out of the overlying coating 214 of the recording medium with the high permeability under layer 212 of the recording medium causing the lines of flux to pass through the overlying coating 214 in a direction generally perpendicular to the surface of the medium to record information in the overlying coating 214 of magnetic material preferably having a high coercivity relative to the under layer 212 in the form of magnetic impulses having their axes of magnetization substantially perpendicular to the surface of the medium. The flux is channeled by the soft underlying coating 212 back to the return layer (P1) of the head 218.

FIG. 2E illustrates a similar structure in which the substrate 216 carries the layers 212 and 214 on each of its two opposed sides, with suitable recording heads 218 positioned adjacent the outer surface of the magnetic coating 214 on each side of the medium, allowing for recording on each side of the medium.

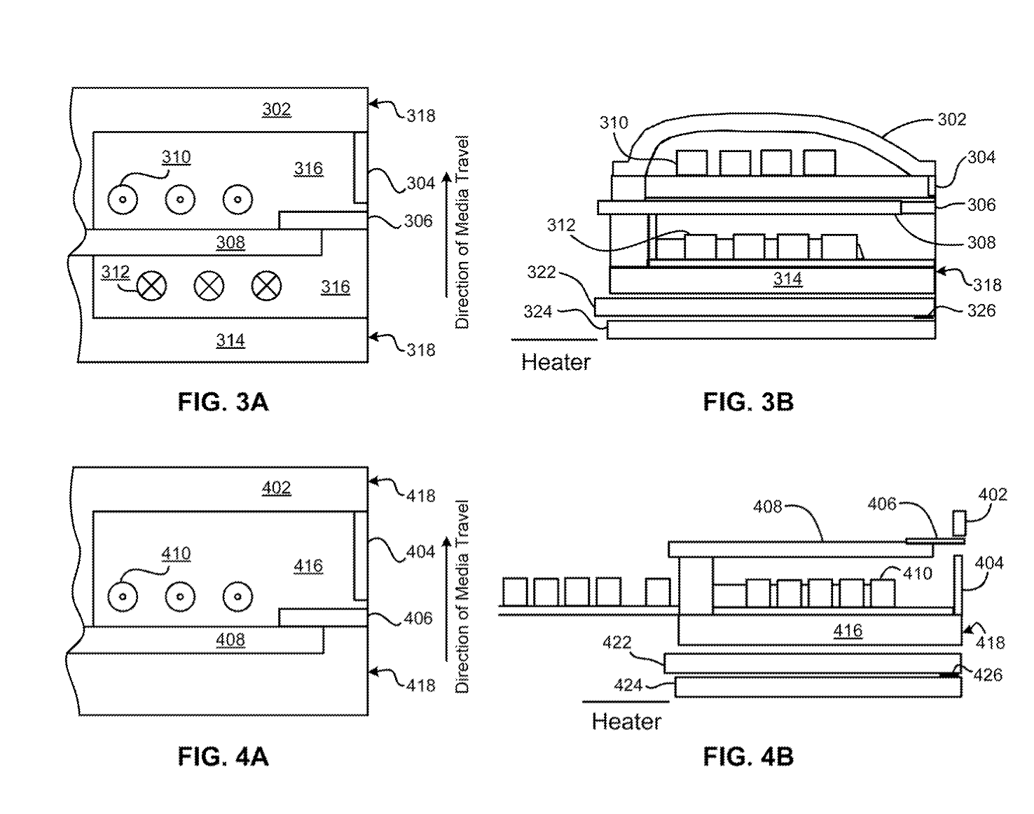

FIG. 3A is a cross-sectional view of a perpendicular magnetic head. In FIG. 3A, helical coils 310 and 312 are used to create magnetic flux in the stitch pole 308, which then delivers that flux to the main pole 306. Coils 310 indicate coils extending out from the page, while coils 312 indicate coils extending into the page. Stitch pole 308 may be recessed from the ABS 318. Insulation 316 surrounds the coils and may provide support for some of the elements. The direction of the media travel, as indicated by the arrow to the right of the structure, moves the media past the lower return pole 314 first, then past the stitch pole 308, main pole 306, trailing shield 304 which may be connected to the wrap around shield (not shown), and finally past the upper return pole 302. Each of these components may have a portion in contact with the ABS 318. The ABS 318 is indicated across the right side of the structure.

Perpendicular writing is achieved by forcing flux through the stitch pole 308 into the main pole 306 and then to the surface of the disk positioned towards the ABS 318.

FIG. 3B illustrates a piggyback magnetic head having similar features to the head of FIG. 3A. Two shields 304, 314 flank the stitch pole 308 and main pole 306. Also sensor shields 322, 324 are shown. The sensor 326 is typically positioned between the sensor shields 322, 324.

FIG. 4A is a schematic diagram of one embodiment which uses looped coils 410, sometimes referred to as a pancake configuration, to provide flux to the stitch pole 408. The stitch pole then provides this flux to the main pole 406. In this orientation, the lower return pole is optional. Insulation 416 surrounds the coils 410, and may provide support for the stitch pole 408 and main pole 406. The stitch pole may be recessed from the ABS 418. The direction of the media travel, as indicated by the arrow to the right of the structure, moves the media past the stitch pole 408, main pole 406, trailing shield 404 which may be connected to the wrap around shield (not shown), and finally past the upper return pole 402 (all of which may or may not have a portion in contact with the ABS 418). The ABS 418 is indicated across the right side of the structure. The trailing shield 404 may be in contact with the main pole 406 in some embodiments.

FIG. 4B illustrates another type of piggyback magnetic head having similar features to the head of FIG. 4A including a looped coil 410, which wraps around to form a pancake coil. Also, sensor shields 422, 424 are shown. The sensor 426 is typically positioned between the sensor shields 422, 424.

In FIGS. 3B and 4B, an optional heater is shown near the non-ABS side of the magnetic head. A heater element (Heater) may also be included in the magnetic heads shown in FIGS. 3A and 4A. The position of this heater may vary based on design parameters such as where the protrusion is desired, coefficients of thermal expansion of the surrounding layers, etc.

According to various embodiments described herein, a magnetic head comprises an air bearing surface overcoat (ABSOC) film formed on the ABS of the magnetic head. According to preferred embodiments, the ABSOC film is capable of being made thinner than in the prior art due to the formation and presence of a protective film that has superior wear resistance and higher density than conventional protective films.

To achieve this, a magnetic head according to one embodiment introduces hydrogen and/or water vapor into a formation chamber as the protective film of the ABSOC film is being formed, with the protective film being characterized in that it comprises water vapor and/or gaseous hydrogen compounds after formation. As a result, it is possible to form a protective film with superior wear resistance and higher density than conventional protective films; and it is further possible to reduce the overall thickness of the ABSOC film.

A method of manufacture for the magnetic head, according to one embodiment, includes: a process which forms at least one of: a write element, a heater element, a read element, and a resistance detector element above a substrate. The substrate, in some approaches, may comprise Al₂O₃—TiC. In more approaches, at least one of each of the write element, the read element, the heater element, and the resistance detector element may be formed, thereby producing a complete magnetic head capable of reading and/or writing to a magnetic medium. The resistance detector element may be used in order to cut the magnetic head from a row bar comprising a plurality of magnetic heads, and the heater element may be used for thermal fly-height control (TFC) during reading and/or writing, according to one embodiment.

The method also includes a process which forms conductive terminals for each of the at least one read element, write element, and heater element. The conductive terminals may comprise gold, silver, copper, platinum, or any other suitable material as would be known to one of skill in the art.

Furthermore, the method includes a process for cutting the substrate into at least one row bar in which a plurality of magnetic heads are connected, a process for polishing the ABS such that the height of the magnetic head elements within the row bar are made uniform while measuring the resistance of the resistance detector element, and a process of forming the ABSOC which introduces hydrogen and/or water vapor into the protective film. The protective film, in some approaches, may comprise DLC and may be formed using an arc-discharge technique. In another embodiment, the ABSOC film may comprise an adhesive layer below the protective layer.

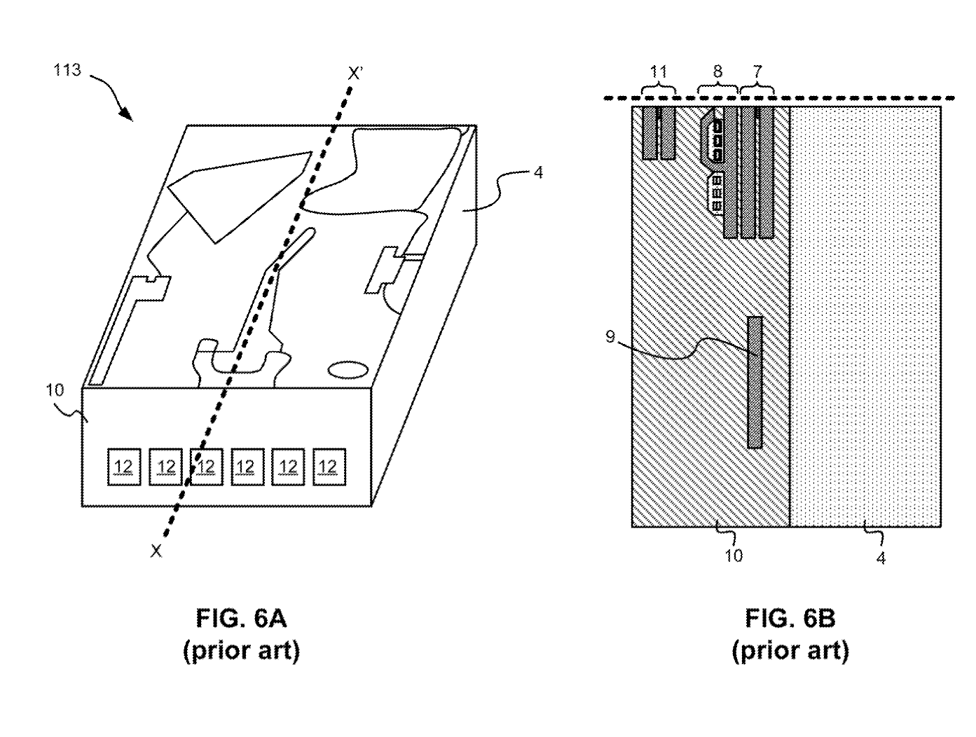

FIG. 6A shows a schematic view of a magnetic head according to the prior art, with FIG. 6B illustrating its cross-section. As shown in FIG. 6B, magnetic head 3 has overcoat film 10 formed thereon comprising alumina (Al₂O₃) which has a purpose of protecting all the elements, including read element 7, write element 8, and heater element 9 formed on the end surface of the substrate 4 comprising Al₂O₃—TiC. Moreover, in the vicinity of the read element is formed a resistance detector element 11 used in the ABS polishing process. Each of the elements are connected to gold terminals 12 formed at the head slider side surface via lead wires, as shown in FIG. 6A. At the same-time, an ABSOC film is formed on the ABS of the magnetic head 3 which is the surface facing the magnetic disk with the purpose of preventing wear on the elements due to contact with a magnetic disk and to prevent corrosion of the elements.

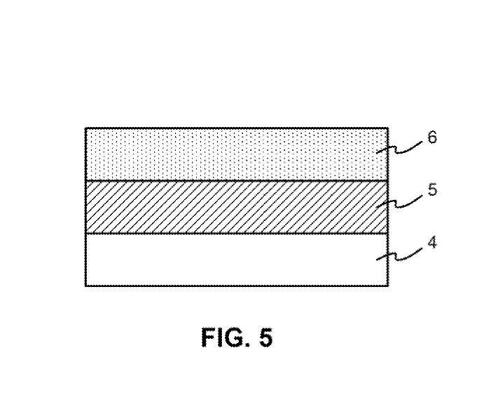

The ABSOC film, as shown in FIG. 5, may have a dual-layer structure, in one embodiment, comprising an adhesive layer 5, and a DLC protective film 6 above a substrate 4. In other embodiments, the ABSOC film may be a single layer film comprising DLC. A silicon or a silicon compound, which may be formed using a sputtering method in some approaches, may be used as the adhesive layer 5. The adhesive layer may have a thickness in a range from about 0.1 nm to about 2.0 nm, in one approach. Of course, other thicknesses may be used as would be apparent to one of skill in the art upon reading the present descriptions. A DLC layer formed using a cathodic arc film-forming process may be used in the protective film 6, in one approach.

According to some embodiments, the DLC protective film 6 may comprise hydrogen, with the proviso that the DLC protective film 6 does not comprise water vapor. In alternative embodiments, the DLC protective film 6 may comprise water vapor, with the proviso that the DLC protective film 6 does not comprise hydrogen.

The method for forming a magnetic head, according to another embodiment, includes the following processes. Of course, more or less manufacturing steps may be used in forming the magnetic head, as would be apparent to one of skill in the art upon reading the present descriptions.

One or more of a read element 7, a write element 8, and a heater element 9 are formed using thin film processes, such as plating, sputtering, etc., above a substrate 4. The substrate may comprise Al₂O₃—TiC and may be in the form of a wafer, such as a wafer having a diameter of 5 inches. Of course, other substrates may be used as would be apparent to one of skill in the art upon reading the present descriptions.

An overcoat film 10, comprising alumina in some approaches, is formed to cover the elements using sputtering or the like. The substrate 4 is cut into at least one row bar with an array having a plurality of magnetic heads therein, such as in a grinding process using a whetstone.

A final polishing process may be carried out on the ABS of the row bar. This process determines the height of the elements, which is the dimension of the elements in the direction facing the magnetic disk. The polishing process measures the resistance of resistance detection element 11 in the process, and partially suppresses the polishing pressure applied to the row bar after using the resistance value in calculating the height of the elements so that the height of the elements on the row bar is about constant. The magnetic head ABS maybe cleaned using splutter etching or the like, and an ABSOC film is formed using a film-forming device or film-forming method, which is described later. To ensure the magnetic head can float at an order of nanometers from the HDD, an ABS rail may be formed on the row bar ABS, such as by using ion milling. Then, using a slicing process, the row bar is divided into individual magnetic heads.

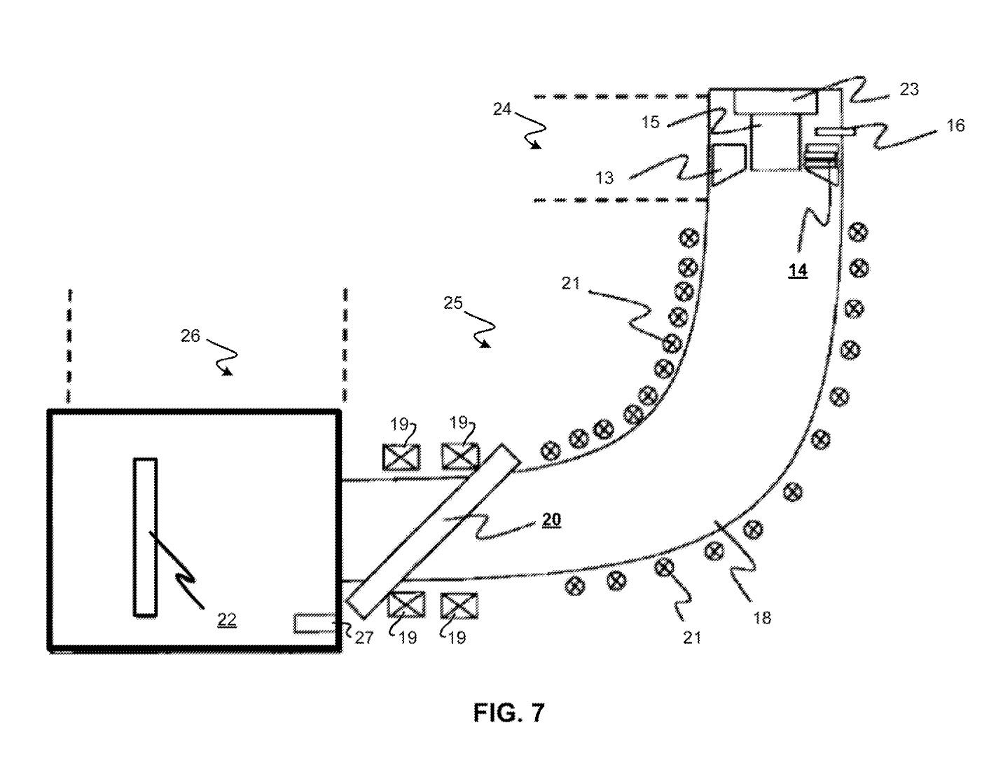

FIG. 7 illustrates a schematic view of a cathodic arc film-forming device that may be used as the ABSOC film-forming device in the method described above. As shown in the diagram, the film-forming device comprises a plasma generator 24, a transfer unit 25, and a film-forming chamber plasma 26. It should be noted that a vacuum is created within the film-forming device using an exhaustion device. Plasma generator 24 is provided with cathode 23 mounted with target 15, anode 13 to which cathode 23 is fixed, and igniter 14 which generates an arc discharge. When forming a DLC film, carbon graphite is used as the target 15. Cathode unit 23 is connected to the negative terminal of an arc discharge source (a fixed current source). Anode 13 is connected to igniter 14, the arc source positive terminal is held at earth potential, and cathode 15 and anode 13 are electrically insulated from one another by insulating material.

Furthermore, gas intromission aperture 16 is provided to introduce argon gas with the purpose of stabilizing the carbon plasma generated by plasma generator 24. Plasma transfer unit 25 is comprised of curved toroidal duct 18, parallel coil 19, inclined coil 20 and magnetic coil 21 around its circumference. Magnetic coil 21 is supplied with an excitation current from a power source. Plasma transfer unit 25 and plasma generator 24 are fixed to one another with insulating material between them, with both being electrically isolated from one another. Substrate stage 22 is provided within formation chamber 26, with the row bar that is the subject of the film forming being mounted on this substrate stage 22.

An outline of the film-forming process will now be described. A DC voltage is applied between target 15 and igniter 14 to generate an arc discharge. When the arc discharge is generated a plasma is created, and with this plasma a cluster comprising a plurality of carbon atoms known as microparticles are discharged in addition to carbon ions discharged from target 15. Argon gas is introduced from gas intromission aperture 16 with the purpose of stabilizing the plasma state containing the carbon ions, forming an argon and carbon mixed plasma. An axial magnetic field is formed in plasma transfer unit 25 by magnetic coil 21, and the mixed plasma including carbon ions and microparticles generated by the arc discharge is concentrated by this axial magnetic field and introduced to toroidal duct 18 of the plasma transfer unit. Also in plasma transfer unit 25, an axial magnetic field is formed along the axis of toroidal duct 18 by magnetic coil 21 provided around toroidal duct 18, the plasma being conducted along this magnetic field. Where the plasma bends at the curved part of toroidal duct 18, electrically neutral microparticles pass on directly without change and are trapped by the toroidal duct 18, but with the addition of a positive bias voltage, further by parallel coil 19, electrically negatively charged electrons and particles or atoms comprising atomic level foreign matter are selectively excluded, so that only good quality carbon ions are selected.

Finally carbon ions with an energy of about 30 eV to about 120 eV, carbon ions deflected by inclined coil 20, are irradiated onto the row bar on substrate stage 22, and a DLC protective layer 6 is formed on the ABS of the row bar.

Of course, other materials and operating conditions may be used according to various embodiments. With the above described embodiment, when forming a film by irradiating a plasma beam onto substrate stage 22, a quantity of water vapor adjusted to a fixed amount may be supplied by mass flow control or the like through gas intromission unit 27, in one approach.

The prescribed water vapor partial pressure or hydrogen partial pressure is preferably around 1×10⁻⁴ Pa—1×10⁻⁶ Pa, in one approach. Where water vapor is supplied via the plasma beam route, the oxygen molecules and hydrogen molecules are stimulated by the plasma generating oxygen radicals O⁺ and hydrogen radical H⁺. At this time, the oxygen radicals O⁺ react selectively with the weak C—C bond (sp2) within the carbon film, C—O bond and the like, and as they are expelled from the film, it is possible to form DLC mainly comprising the strong C—C bond (sp3). In addition, although films formed using the cathodic arc method are dense and hard films, they have the defect of being brittle due to the high compressive stress, but bonding between the hydrogen radical H⁺ and the carbon relieves the stress within the film and improves its pliability.

### Experimental Results

The results of experimental comparison between the film quality of some embodiments of an ABSOC protective film formed using the methods disclosed herein against an ABSOC protective film formed using conventional techniques is described in detail below.

In one embodiment, a sample of one embodiment was created under the conditions of an arc current of 70 A, argon gas flow of 2 sccm, water vapor pressure of 5×10⁻⁵ Pa, forming protective film 6 on an Si substrate with a thickness of 2 nm. Moreover, a sample using a conventional method was created without introducing water vapor when forming a protective film 6, using only argon gas.

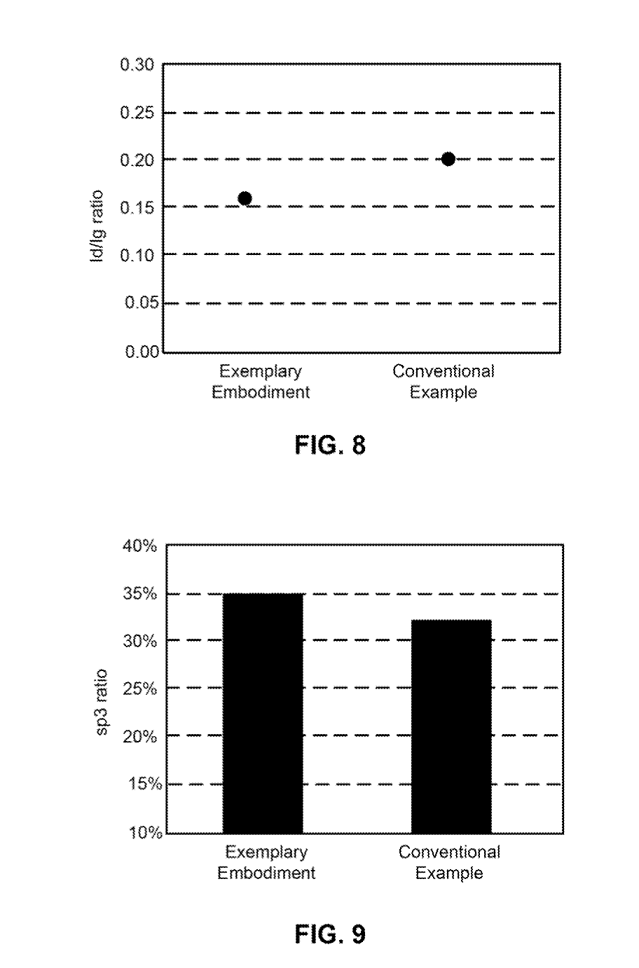

Using a Raman spectroscopy device the D-band peak strength in the vicinity of 1350 cm⁻¹ and G-band peak strength in the vicinity of 1530 cm⁻¹ were measured, and the ratio of the D-band peak strength and the G-band peak strength compared (Id/Ig ratio). The results of this are shown in FIG. 8. The Id/Ig ratio indicates the proportion of the strong C—C bonding (sp3 bonding), with the proportion of sp3 bonding being greater the lower the figure, yielding a dense and hard film quality. As shown in FIG. 8, the peak ratio for the carbon protective film of the embodiment was smaller than the peak ratio for the comparative example, indicating that the sp3 bonding was greater.

In the same way, FIG. 9 shows the results of measuring the proportion of sp3 bonding to other types of bonding (e.g., sp2 bonding) using x-ray electronic spectroscopy. Whereas the sp3 bonding ratio (sp3 bonds/other bonds) for the comparative example was around 31%, the sp3 bonding ratio for the carbon protective film of the embodiment was around 35%, showing that the sp3 bonding of the comparative example was greater.

From the above results, the protective film manufactured using the embodiment is capable of forming a denser and harder protective film as the proportion of sp3 bonding is greater than a conventional protective film.

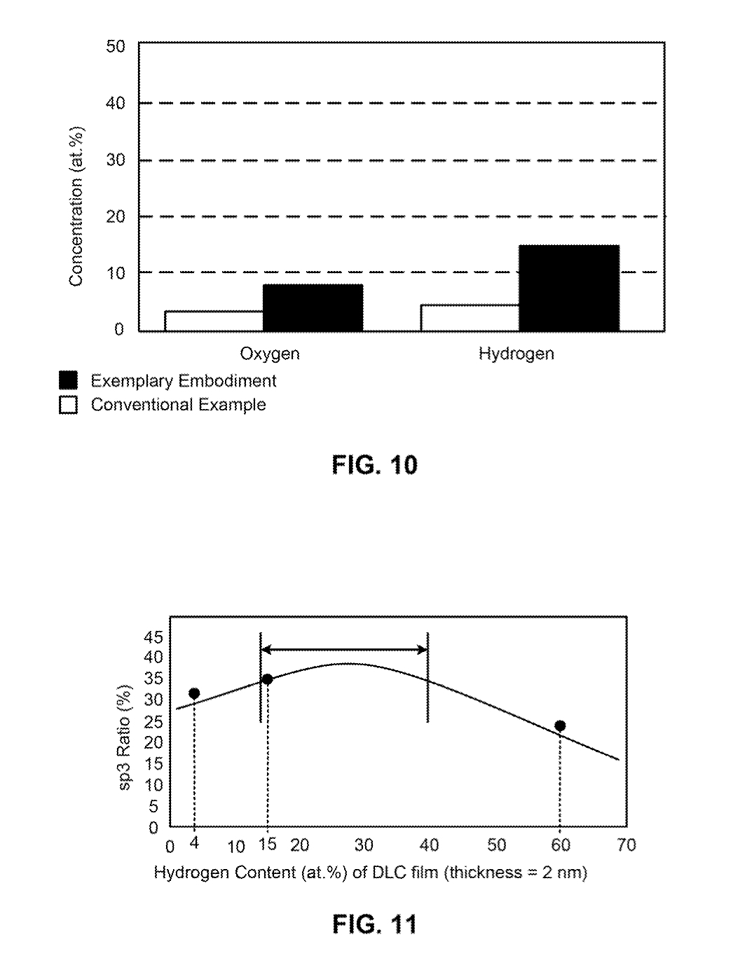

FIG. 10 shows the quantities of elements found from the results of RBS and ERDA analysis using an energy ion beam analysis device. Whereas the proportion of hydrogen in a protective film in the conventional example was around 4 at. %, the figure for the protective film in the embodiment was around 15 at. %, showing that the protective film of the embodiment had a larger hydrogen content. Moreover, with the proportion of oxygen as well, whereas the figure for the protective film in the comparative example was 3 at. %, the figure for the protective film of the embodiment was 8 at. %, showing that the protective film of the embodiment had a large oxygen content. From these results, the protective film of the embodiment is characterized in that it contains a large amount of oxygen and hydrogen.

Normally, with DLC film thicker than about 20 nm, where the hydrogen content is more than about 20%, a weak C—H bonding occurs, and the sp3 ratio of the film is found to reduce, relatively, due to more weak C—H bonds and less strong C—C sp3 bonds. Moreover, in regions of film thinner than about 2 nm, as the hydrogen content is generally high, it can be presumed that the hydrogen content is three times greater than when the film is thicker, and that the C—H bonding increases similarly to thicker film causing a deterioration in film quality. This concept can be arrived at by combining FIG. 10 and the relationship between sp3 bonding and the hydrogen content of DLC film shown in FIG. 11. From the relationship shown in FIG. 11, to obtain a high sp3 ratio, the hydrogen content in a thin-film DLC film needs to be within a range from about 15 at. % to about 40 at. %, and it is likely that as a result the sp3 ratio may be raised to between about 35% and about 40%.

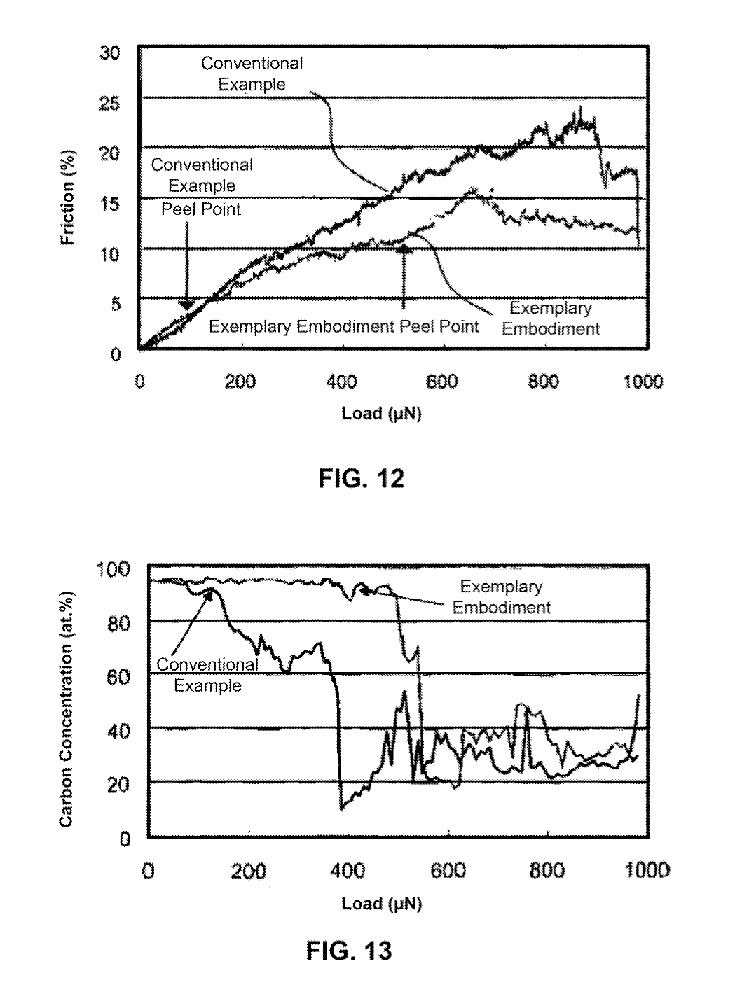

The results of verifying the effect of making the carbon protective film thinner in the magnetic head is now described. The results of the head scratch test are shown in FIG. 12, and the results of an Auger analysis on the scratch marks are shown in FIG. 13. The sample used in the scratch test was a 0.5 nm adhesive film of SiN and a carbon protective film with a thickness of 1.5 nm formed on a row bar ABS. The scratch test machine has a tiny stylus made of diamond attached to the tip of the cantilever, this stylus being moved in one direction with the applied load proportionally increased as this stylus is rubbed against the sample surface with an amplitude of between about 30 nm and about 100 nm.

By carrying out the scratch test, it is possible to find the load at which the thin film breaks or peels by observing the rapid increase in friction response due to the influence of dust particles generated when the thin-film peels or breaks. With these scratch test results for the embodiment (FIG. 12), it can be seen that the friction response increases where the applied load exceeds 500 μN, with the comparative example an increase in the frictional response can be confirmed in regions in excess of an applied load of 100 μN, meaning that the embodiment can be considered to be less likely to peel or break than the comparative example.

FIG. 13 shows the results of spectroscopy of the test in FIG. 12. Auger electron scratch analysis with Auger scratch marks in the electron spectroscopy detects Auger electrons stimulated by an electron beam, and is a method of obtaining information on the types and quantities of elements present on the surface of the test material. When the DLC film is scratched by the diamond stylus of the scratch test machine, the diamond film thickness is reduced. By observing changes in the carbon concentration along the scratch test marks, it is possible to know the changes in the film thickness of the carbon film, enabling an estimation of the load at which peeling or breakage takes place using the scratch test. In the embodiment, whereas a reduction in the concentration of elements is seen when the applied load exceeds 500 μN, in the comparative example a reduction in the concentration of elements is seen for carbon at the point where the applied load exceeds approximately 100 μN.

These results also match the tendency obtained from the scratch test in FIG. 12, so compared to the comparative example, the embodiment can be considered to form a film with high wear resistance in which the carbon film is less likely to peel or break. As a result there is the possibility that it an contribute further to reducing film thickness.

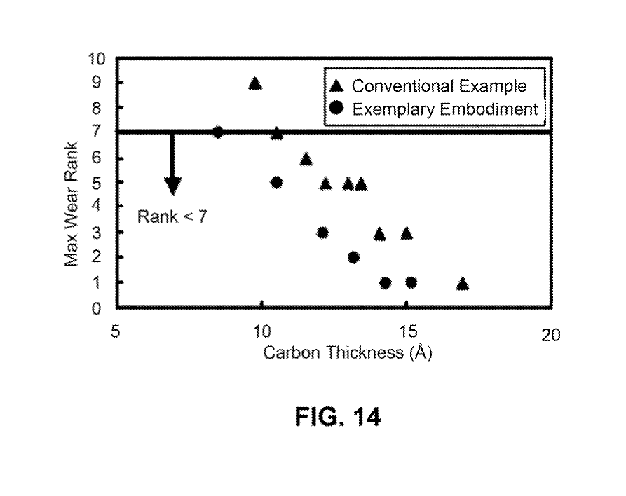

FIG. 14 shows the results of monitoring the levels of wear in the magnetic head protective film with a magnetic head formed with the carbon protective film of the embodiment and the comparative example placed in an HDD and the ABS of the magnetic head deliberately placed in contact with the magnetic disk. As an example, where the carbon protective film thickness was 15 Å, the maximum wear ranking (1) was for the embodiment, whereas the comparative example had a lower ranking (3), so the protective film of the embodiment clearly has better wear resistance than the protective film of the comparative example. Moreover, even in a comparison at the maximum wear ranking where the carbon protective film thickness varied, it is clear that the carbon protective film of the embodiment has a higher wear resistance than the carbon protective film of the comparative example. From these results, using the carbon protective film according to various embodiments described herein makes it possible to have a film that is approximately 2.5 Å thinner, yet more wear resistant.

While various embodiments have been described above, it should be understood that they have been presented by way of example only, and not limitation. Thus, the breadth and scope of an embodiment of the present invention should not be limited by any of the above-described exemplary embodiments, but should be defined only in accordance with the following claims and their equivalents.

1. A method for manufacturing a the magnetic head as recited in claim 10, the method comprising:
forming the protective film, wherein at least one of hydrogen and water vapor are introduced into a formation chamber during formation of the protective film.

2. The method as recited in claim 1, further comprising forming an adhesive layer below the protective film.

3. The method as recited in claim 1, wherein the protective film comprises diamond-like carbon (DLC) and at least one of hydrogen and water vapor.

4. The method as recited in claim 3, wherein a hydrogen content of the protective film after formation is in a range from about 15 at. % to about 40 at. %.

5. The method as recited in claim 3, wherein the protective film is formed through cathodic arc film-formation.

6. The method as recited in claim 3, wherein a sp3 ratio of the protective film after formation is in a range from about 35% to about 40%, wherein the sp3 ratio is defined as an amount of sp3 bonds divided by an amount of other bonds.

7. The method as recited in claim 1, wherein a partial pressure of the at least one of hydrogen and water vapor is maintained in a range from about 1×10⁻⁴ Pa to about 1×10⁻⁶ Pa in the formation chamber.

8. The method as recited in claim 1, wherein the
substrate comprises Al₂O₃—TiC.

9. The method as recited in claim 1, further comprising:
forming at least one of: the read element, the write element, the heater element, and the resistance detector element above the substrate;
forming the conductive terminals for each of the at least one of: the read element, the write element, and the heater element, wherein the substrate and the at least one of: the read element, the write element, and the heater element comprise a structure;
cutting the structure into one or more row bars, wherein each row bar comprises a plurality of magnetic devices; and
polishing an air bearing surface (ABS) of each of the one or more row bars while measuring a resistance of the at least one resistance detector element.

10. A magnetic head, comprising:
at least one of: a read element, a write element, a heater element, and a resistance detector element above a substrate;
conductive terminals for each of the at least one of: the read element, the write element, and the heater element; and
a protective film above the at least one of: the read element, the write element, and the heater element, wherein the protective film comprises at least one of hydrogen and water vapor.

11. The magnetic head as recited in claim 10, wherein the protective film further comprises diamond-like carbon (DLC).

12. The magnetic head as recited in claim 11, wherein the protective film comprises hydrogen, with the proviso that the protective film does not comprise water vapor.

13. The magnetic head as recited in claim 11, wherein the protective film comprises water vapor, with the proviso that the protective film does not comprise hydrogen.

14. The magnetic head as recited in claim 10, further comprising an adhesive layer between the protective film and the at least one of: the read element, the write element, and the heater element, the adhesive layer having a thickness in a range from about 0.1 nm to about 2.0 nm.

15. The magnetic head as recited in claim 10, wherein a hydrogen content of the protective film is in a range from about 15 at. % to about 40 at. %.

16. The magnetic head as recited in claim 10, wherein a sp3 ratio of the protective film is in a range from about 35% to about 40%, wherein the sp3 ratio is defined as an amount of sp3 bonds divided by an amount of other bonds.

17. The magnetic head as recited in claim 10, wherein the protective film has a structure characteristic of being formed in a formation chamber having a partial pressure of at least one of hydrogen and water vapor in a range from about 1×10⁻⁴ Pa to about 1×10⁻⁶ Pa.

18. The magnetic head as recited in claim 10, wherein the substrate comprises Al₂O₃—TiC.

19. A magnetic data storage system, comprising:
at least one magnetic head as recited in claim 10;
a magnetic medium;
a drive mechanism for passing the magnetic medium over the at least one magnetic head; and
a controller electrically coupled to the at least one magnetic head for controlling operation of the at least one magnetic head.
